(19) United States
(12) Patent Application Publication
(10) Pub. No.: US 2014/0069708 A1
(43) Pub. Date: Mar. 13, 2014

(54) COATED SENSOR OR RFID-HOUSING

(71) Applicants: Jörg Groß, Fellbach (DE); Saeed Isfahani, Gerlingen (DE)

(72) Inventors: Jörg Groß, Fellbach (DE); Saeed Isfahani, Gerlingen (DE)

(21) Appl. No.: 13/606,478

(22) Filed: Sep. 7, 2012

(51) Int. Cl. H05K 5/00; B05D 1/36

(52) U.S. Cl. 174/520; 427/409; 174/50

(57) ABSTRACT

A coated sensor or RFID housing is provided including at least one housing cover (1) which is twice coated in at least some areas. The housing cover (1) includes a base (A), on which a first coating (B) of a porous ceramic is provided and on which a second coating (C) is also provided. The base (A) is formed by a metal, the first coating (B) is formed by an oxide ceramic with a lamellar structure and the second coating (C) is formed by a fluoropolymer varnish. The second coating (C) is at least partially incorporated into the first coating (B). The outer structure of the whole coating (4) is formed over the major part of the surface of the structure by the second coating (C) and independently from the structure of the first coating (B).

### FIELD OF THE INVENTION

The invention relates to a coated sensor or RFID-housing, especially a housing for proximity switches, like inductive, capacitive, magnetic or electromagnetic proximity switches, the sensor or RFID housing, comprising at least one housing cover which is twice coated in at least some areas, in which the housing cover including a base, on which a first coating of a porous ceramic is provided and on which a second coating is also provided.

### BACKGROUND OF THE INVENTION

From the DE 195 16 934 C1 an inductive proximity switch is known, in which a metallic cap is arranged at a cylindrical housing.

DE 39 11 598 C2 (U.S. Pat. No. 4,996,408 A) discloses a non-contact electronic proximity switch to be used in welding zones of welding facilities, the responsive sensitive front part of which is provided with a ceramic disc in place of otherwise used plastic caps. The ceramic disc is provided with a non-sticky coating of PTFE or PFA, which also extends on an adjoining bare brass housing.

From the DE 101 63 646 A1 a compound is known, especially for outdoor linings in the construction field, which combines the hardness and wear resistance of inorganic materials with stain and water resistant properties. The compound is formed by three components, in which a substrate is provided, a porous coating structure made of ceramic, metal or cermet and an inorganic-organic nanocomposite material, which fills at least the pores of the second component. Here the surface roughness of the porous layer is slightly reduced by the nanocomposite material.

DE 10 2009 049 137 A1 (US 2011/0212296 A1) discloses a non-stick coating for a surface of a substrate. In order to significantly improve the non-stick properties compared to the previously known surface coatings and to ensure adequate stability, the surface coating contains at least one fluoropolymer with at least one microstructured first layer and at least one submicrostructured second layer overlaying the latter, as well as a process for the production of a surface coating, in which the microstructured subsurface is produced by applying a microstructured layer on a macro structured surface. Herein a hierarchical layer structure is provided, in which the first layer having a first surface structure is overlaid with a microstructure with elevations in the range from 2 to 50 μm, the second surface structure of the second layer having a structure in the submicrometer range (especially in an range from 0.1 to 5 μm), without that the first surface structure on it has equalized levels (see FIG. 2 of DE 10 2009 049 137 A1).

### SUMMARY OF THE INVENTION

An object of the invention is to provide a coated sensor or RFID-housing, which can be used in an welding area, in which welding drops preferably do not stick at the coated area of the housing so that in case of sticking they can be easily removed from the surface of the housing without damage.

This object is reached according to the invention by means of a coated sensor or RFID-housing comprising a housing cover comprising a base formed by a metal and a double coating on at least one area of the base. The double coating comprises a first coating of a porous ceramic on the base, the first coating being formed by an oxide ceramic with a lamellar structure and a second coating provided on the first coating to provide the double coating. The second coating is formed by a fluoropolymer varnish. The second coating is at least partially incorporated into the first coating, wherein an outer surface structure of the double coating is an outer surface structure of the second coating over a major part of the outer surface structure of the double coating and the outer surface structure of the double coating is independent from a structure of the first coating.

According to the invention the sensor or RFID-housing, especially a housing cover, is formed by a base made of metal, especially steel, preferably stainless steel, possibly also brass, aluminum, die-cast zinc, by a first coating of a ceramic oxide, especially by a coating of Aluminum-Titanium oxide, or aluminum oxide, titanium oxide, chromic oxide, yttrium-stabilized zirconia, magnesium oxide as well as their mixture, as well as alloy constituents, with a lamellar structure, and by a second coating of a fluoropolymer varnish. Especially the area that constitutes the area provided with the two layered coating, is one through which a sensor is placed in the housing. By means of the two layered coating of the housing excellent properties result with regard to the abrasion resistance, impact resistance as well as excellent non-stick properties, so that cleaning the housing is possible for example by means of a metal brush without damaging the coatings.

In particular the lamellar structure of the first coating of an oxide ceramic, preferably with large and small lamellas, which are very hard, gives the first coating an excellent wear resistance, particularly in the area of the “peaks” of the surface, which are preferably covered only with a relatively small layer of the second coating of the fluoropolymer varnish. These peaks of the first coating are the ones which significantly contribute to the stability of the whole coating, but they have also a positive influence on the non-sticky effect of the whole coating. However altogether the outer structure of the whole coating over the major part of the surface is formed by the structure of the second coating and independently from the structure of the first coating, i.e. the application of the second coating modifies the surface structure, wherein during the application itself the original surface structure of the first coating is maintained and by means of the application of the second coating a clearly distinguishable surface structure is formed thereon. An outer surface structure of the double coating is an outer surface structure of the second coating over a major part of the outer surface structure of the double coating and the outer surface structure of the double coating is independent from a structure of the first coating.

The oxide ceramic is applied by means of thermal spraying, for example by means of plasma processes, high-speed processes, powder or wire flame spraying or electric arc processes. The application preferably occurs by means of flame spraying methods using a roughing powder.

By means of the fluoropolymer varnish of the second coating, very good non-stick properties results, and moreover this second coating is very stable in temperature. For example, this leads to the fact that welding drops do not adhere on the surface of the coating.

The excellent elasticity of the fluoropolymer varnish of the second coating in connection with the elasticity of the first coating due to the lamellar structure and thin layer thickness and in connection with the very good adhesion of the first coating on the base and of the second coating on the first coating moreover result in a deformability of the whole housing cover, preventing one or both coatings to flake off.

The second coating according to the invention substantially modifies the shape of the surface of the first coating, and in particular it completely or partially fills the pores in the surface area of the first coating, the surface roughness being equalized, i.e. valleys are filled, and at least the areas between peaks of the first coating are filled, in particular the whole surface of the first coating is covered with the second coating. However, the use can lead to a removal of the second coating especially in the area of the peaks, wherein the operability of the whole coating is not affected or it is only partially affected.

The surface roughness depth Ra (Roughness Average) of the second coating preferably is 2.4 to 4.9 μm, particularly preferably 2.7 to 4.5 μm and more preferably 3.03 to 4.11 μm.

The surface roughness depth Rz (Average Maximum Height of the Profile) of the second coating preferably is 13.5 to 30.0 μm, particularly preferably 15.2 to 27.5 μm and more preferably 16.96 to 25.02 μm.

Preferably the first coating shows a porosity from 0.9 to 20.0 Vol.-%, particularly preferably from 1.0 to 15.0 Vol.-%. In comparison with these values, possible porosity of the base and of the second coating is negligibly small.

By providing a porosity of the first coating inside the layer, the propagation of micro-cracks is prevented and at the outer side of the layer, i.e. near the second coating, one of the material of the second coating is deposited in the pores, so that result a “micro-pot”. The surface roughness depth of the first coating also favors the incorporation of the second coating, so that a kind of reciprocal clawing penetration of the two layers occurs.

The surface roughness depth Ra of the first coating preferably is 3.5 to 6.5 μm, particularly preferably 3.9 to 5.9 μm and more preferably 4.39 to 5.40 μm.

The surface roughness depth Rz of the first coating preferably is 20.0 to 41.0 μm, particularly preferably 23.0 to 37.0 μm and more preferably 25.60 to 34.20 μm.

Each of the surface roughness depth Ra and Rz of the base and the surface roughness depth Ra and Rz of the second coating preferably are smaller than the surface roughness depth Ra and Rz of the first coating. This guarantees good adhesion and penetration of the repellent and at the same time the safe protection of second coating with reference to the first coating.

The surface roughness depth Ra and Rz of the base preferably differs not more than about 10% with reference to the surface roughness depth Ra and Rz of the second coating.

The penetration depth of the first coating into the base is smaller than the penetration depth of the second coating into the first coating, so that the second coating adheres in a particularly good way to the first coating.

It is advantageous when the penetration depth of the second coating into the first coating is equal to the surface roughness depth Ra of the first coating, even better when it is greater than the same, since in this way on the surface are also present porosities of the first coating which are at least partially filled with the second coating, as a result of which the reciprocal clawing penetration of the two layers clearly improves and thus the load bearing capacity of the second coating is increased.

The thickness of the second coating is preferably smaller or equal to the penetration depth of the second coating into the first coating. It is also possible that the thickness of the second coating is only formed by a wetting film, so that by far the maximum part of the material of the second coating is incorporated in the uneven rough surface of the first coating.

The penetration depth of the second coating (C) in the first coating preferably is 3.6 to 50.0 μm, particularly preferably 4.0 to 40.0 μm, and more preferably 5.0 to 25.0 μm.

Particularly preferably only a portion of the housing is provided with both coatings. The remaining part of the housing or a greater area, which does not include the sub-section, in this case is preferably provided with only one of the two coatings, particularly preferably only with the second coating.

In the following the invention is explained on the basis of an embodiment with variants with reference to the included drawings. The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

FIG. 1 is a schematic sectional view of a wall of the housing according to an embodiment of the invention;

FIG. 2a is a top view on the housing according to the embodiment of the invention;

FIG. 2b is a sectional view along line II-II in FIG. 2a;

FIG. 2c is a side view of the embodiment shown in FIG. 2a;

FIG. 2d is a perspective view of the housing of the embodiment shown in FIG. 2a;

FIG. 2e is another perspective view of the housing of the embodiment shown in FIG. 2a;

FIG. 3a is a top view of a sensor arrangement with the housing of the embodiment shown in FIG. 2a;

FIG. 3b is a partial side view of the embodiment shown in FIG. 3a;

FIG. 4 is an enlarged section view through the housing of the shown embodiment;

FIG. 5 is an enlargement of the detail V in FIG. 4; and

FIG. 6 is a further, more enlarged sectional view through the housing according to the embodiment of the invention.

### DESCRIPTION OF THE PREFERRED EMBODIMENTS

Referring to the drawings in particular, according to a preferred embodiment a housing cover 1 for an inductive proximity switch 2 is provided. In this case, the proximity switch 2 is intended to be used near a not represented welding robot, i.e. it is exposed to welding drops.

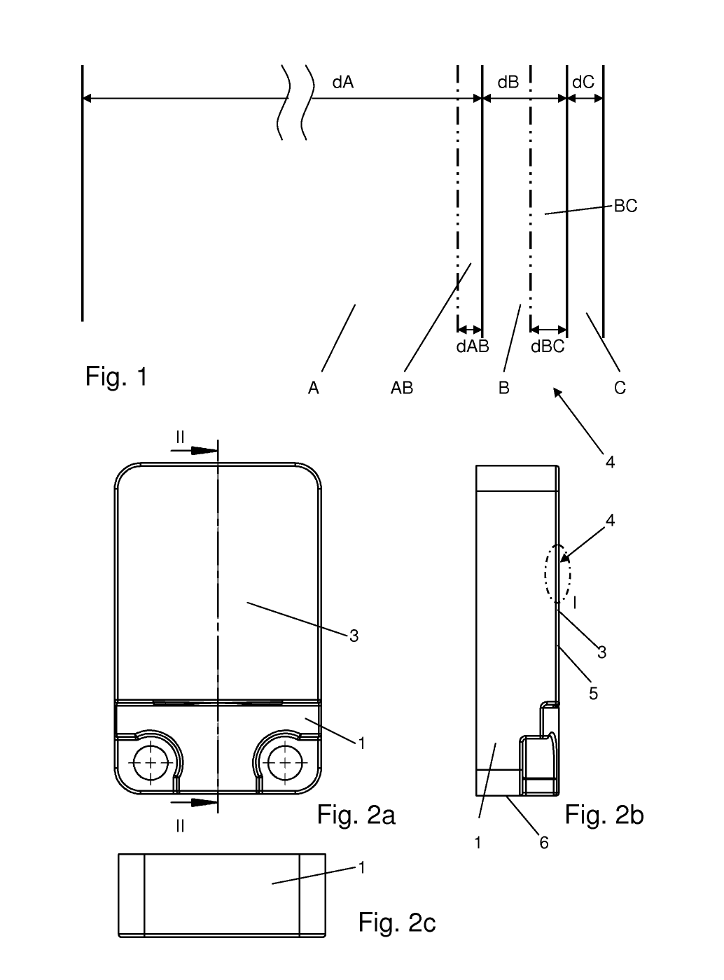

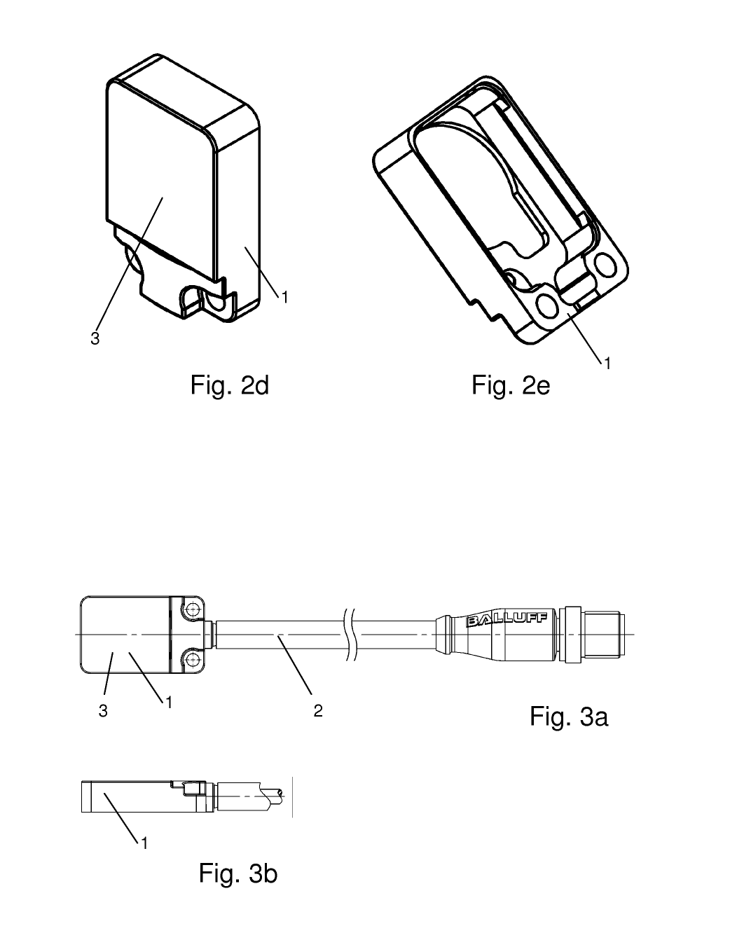

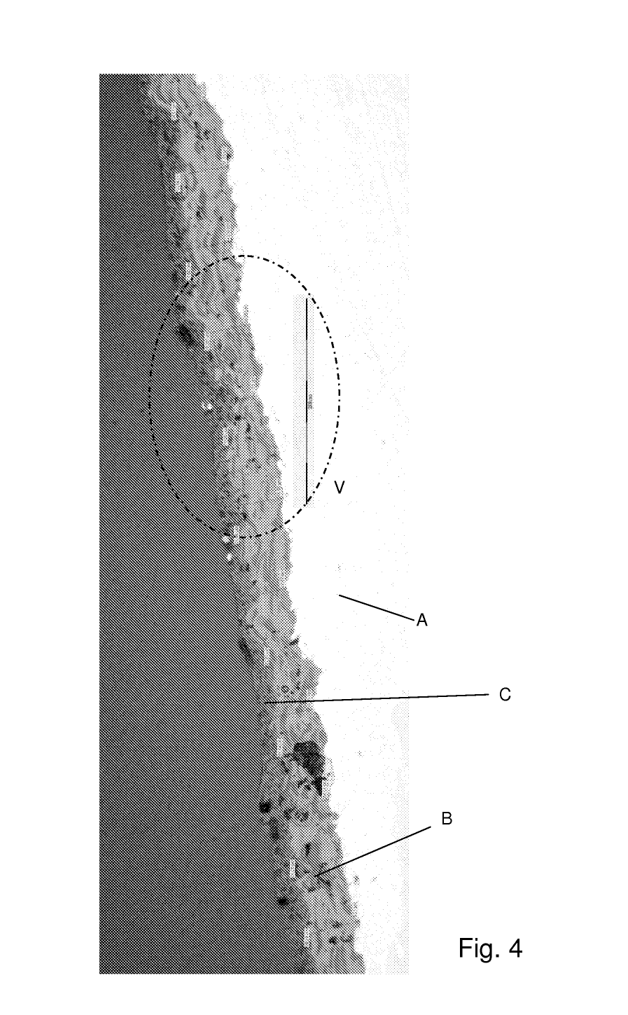

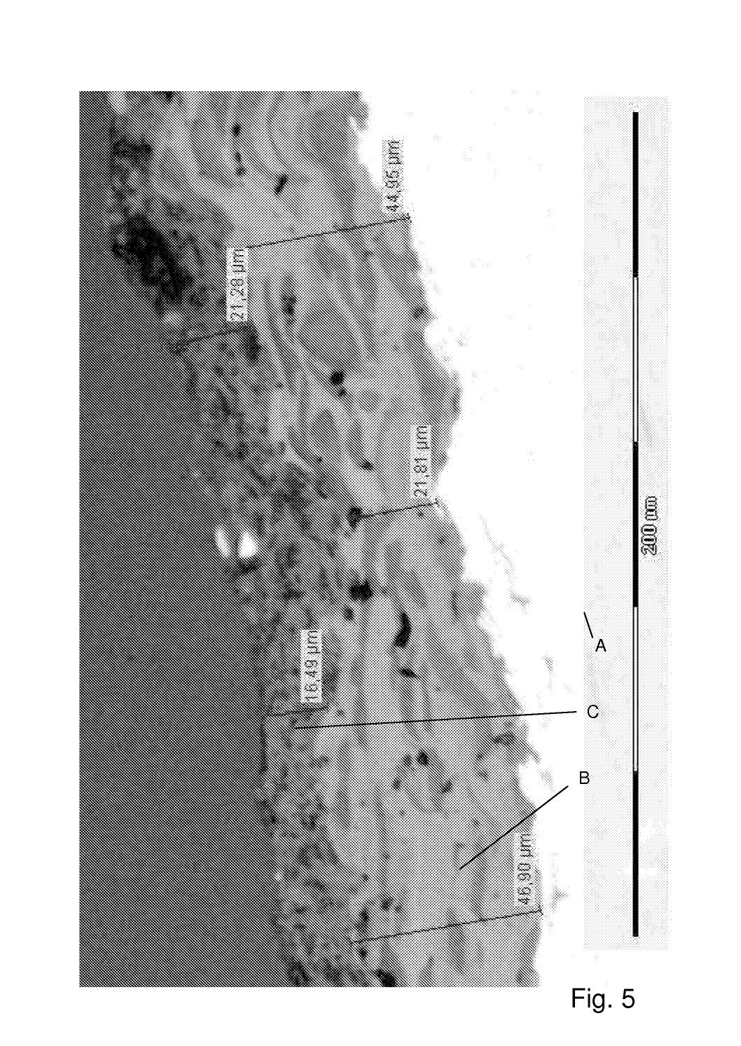

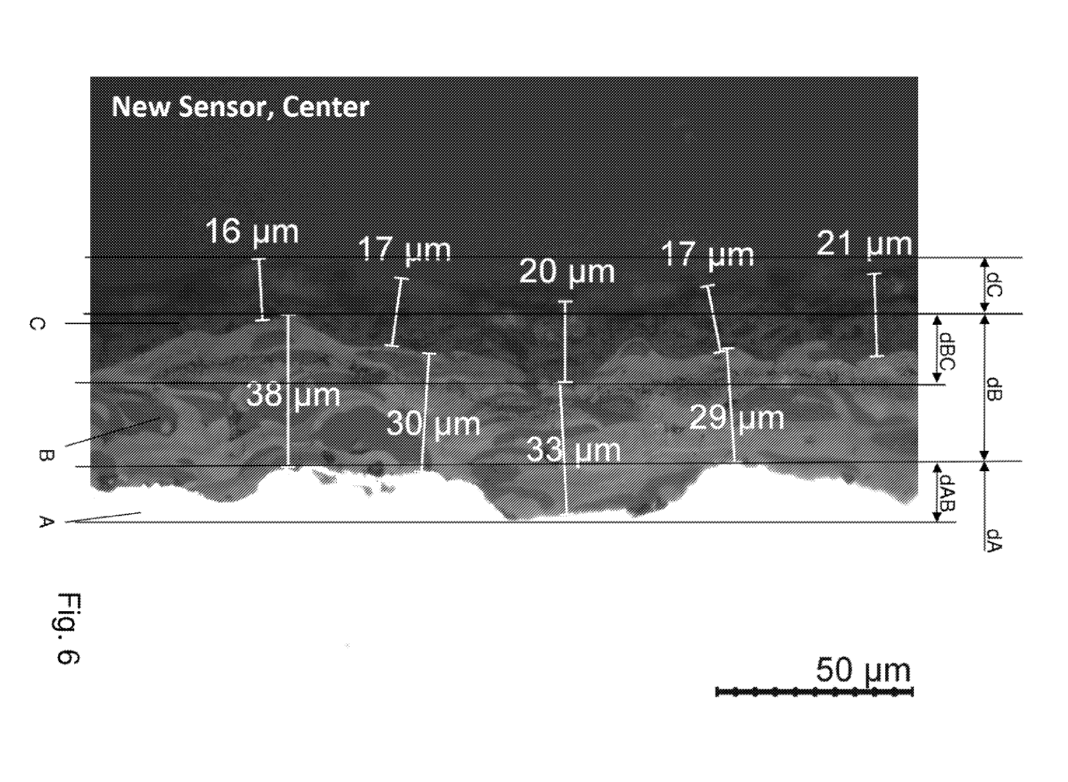

The housing cover 1, which is fixed at a not represented housing base and together with which it constitutes a housing, has in this case, a length of about 32 mm, a width of about 20 mm and a thickness of about 8 mm. A sensor arrangement is provided inside the housing, by means of which a housing wall 3 of the housing cover 1 is measured, and it can be seen in FIG. 2a. In FIG. 1 a very schematic section perpendicularly through this housing wall 3 is illustrated, wherein the thickness sizes of layers are not reproduced in scale to better represent the basic layer structure.

In this case, in the assembled state, the housing cover 1 is provided in correspondence with all of its external surfaces with a two layered coating 4, i.e. in correspondence with the upper side 5 and in correspondence with the side walls 6 of the housing cover 1. The coating 4 is provided on a base A, formed by the material of the housing cover 1, wherein a first coating B on the base A and a second coating C on the first coating B are formed. Here, in any case, between the base A and the first coating B a first mixing layer AB is present and between the first coating B and the second coating C a second mixing layer BC is present. In the following, the thickness of the base A will be indicated with dA, the thickness of the first coating B will be indicated with dB and the thickness of the second coating C will be indicated with dC, in which dA+dB+dC results in the total thickness of the housing cover 1, in the case of the present outer double coating 4. The thicknesses dAB and dBC of the mixing layers AB or BC respectively refer to the distance of the outmost points of the outer surface of the base A or of the first coating B and the maximum penetration depth of the first coating material of the first coating B or the second coating material of the second coating C.

According to the present embodiment the material of the base A is in an austenitic steel, I. e. X2CrNiMo17-12-2, which in this case is slightly magnetizable. This steel has a density of about 8.0 kg/dm³ at 20° C., a thermal conductivity at 20° C. of about 15 W/mK at 20° C., a specific effective heat capacity of about 500 J/kgK at 20° C., a specific electric resistance of 0.75 Ohm mm²/m at 20° C. The structure is austenitic with small ferrite portions.

Particularly X8CrNiS18-9 can be used as an alternative to X2CrNiMo17-12-2.

The whole housing cover 1, particularly the surface of the base A to be coated, is sandblasted and degreased, and it is roughened with Ra of about 2.4 to 4.1 μm and Rz of about 17.0 to 27.0 μm. In this case, the thickness dA of the housing cover 1, i.e. of the base A, is about 0.5 mm or 1 mm (see FIG. 2e), but it has in principle no influence on the operability of the coating 4.

The first coating B is formed by Aluminum-Titanium oxide with essentially negligible, further alloying constituents. In this case the mixing ratio Al₂O₃:TiO₂ particularly preferably is about 6:4, in which the mixing ratio Al₂O₃:TiO₂ preferably lies in the range from 1:1 to 87:13. Here this first coating is applied on the accordingly prepared surface of the base A by means of thermal spraying, in this case by means of powder flame spraying.

The first coating B has in this case a density of about 4.1 g/cm³, which is formed porous by applying thermal spraying with the lamellar structure, in this case with a porosity of about 5 Vol-%. It has a melting point of about 1840° C.

By using particles having a different size for starting material of the first coating B in the flame spraying, lamellas having a different size are obtained, i.e. the result is a lamellar structure with a mixture of large and small lamellas. Here, the small lamellas act as hinges between the large lamellas, so that a large elasticity of this layer, i.e. of the first coating B, is achieved.

In this case the thickness dB of the first coating B is a little less than 40 μm (see FIG. 6). Here the first coating B has penetrated forming a first intermediate zone or mixing layer AB into the base A, resulting in a thickness dAB of the mixing layer of about 16 μm (see FIG. 6). Out of prevention it should be noted that the concept of mixing layer refers to an area in which both material types are present, which however do not mix with each other or only mix a little with each other, i.e. this is a sort of “dig zone”. In particular, the mixing layer AB is determined by the surface roughness, but also by the capability of the applied material to penetrate in cavities.

The surface of the first coating B, having Ra of about 4.9 μm+/0.5 μm and Rz of about 26.0 to 33.0 μm, has a greater roughness than the sanded surface of the base A.

The porosity of the first coating B has besides the surface roughness of the first coating B a substantial influence on the application and adhesion of the second coating C, i.e. on the operability and durability of the whole coating 4 of the housing cover 1.

The second coating C is formed by a fluoropolymer varnish, in this case with a PTFE varnish with a thermosetting organic resin as binding agent and a solvent agent. The fluid varnish is applied in this case by means of spraying on the first coating B, wherein the application can alternatively occur for example also by means of vaporization, electrostatic spraying, by means of dip varnishing or it can be applied by means of a brush or a roller. No special preparation for the first coating is required.

The thickness dC of the second coating C is a little less than 19 μm (see FIG. 6). Here the second coating C has penetrated forming a second intermediate zone or mixing layer BC into the first coating B, resulting in a thickness dBC of the mixing layer BC of about 19 μm (see FIG. 6). For the mixing layer BC same considerations apply as for the mixing layer AB. It is pointed out for reasons of precaution that, due to the definition of the outer surface, a “non existing” thickness dC of the second coating is possible. This especially occurs when all of the material of the second coating C are held in the rough and porous surface of the first coating B, therefore resulting a relatively large thickness dBC of the mixing layer BC. The majority of the outer surface is still made of the material of the second coating C. Only the tips of the first coating B reach out in between the “lake-like” structure of the second coating C. The majority of this outer surface is still made of the material of the second coating C—it is formed of the second coating over a major part of the outer surface structure of the double coating.

The surface of the second coating C is significantly smoother than the surface of the first coating B and it lies for example in the area of the surface roughness of the sanded surface of the base A, wherein in this case the surface roughness has values Ra about 3.1 to 4.1 μm and Rz about 17.0 to 25.0 μm.

As a whole, the relatively thin configuration of the first coating B on the base A in connection with the porous lamellar structure of the ceramic applied by means of thermal spraying results in an excellent impact resistance of the coated surface. The porous lamellar structure of the ceramic also entails an improved holding action on the base A and in particular it offers to the second coating C an optimal surface to prevent a detachment of the same, wherein the second coating C can penetrate with a clawing action into the first coating B due to the porous lamellar structure, i.e. it is secured in a very good way against a flake detachment.

The porous lamellar structure of the first coating B is also advantageous considering possible cracking and crack propagation within the layer, since crack growth is hindered by this porous lamellar structure, i.e. a structure with interruptions, so that only localized micro-cracks arise i.e. inside a few lamellas, micro-cracks are present, which do not further diffuse.

The wear resistance of the surface of the whole coating 4 is improved by means of the porosity of the first coating B, which allows a penetration of the non-sticky coating material of the second coating C into the pores between the lamellas, in particular the duration of the wear resistance is improved compared to conventional coatings, which do not penetrate in pores.

In this case the (overall) coating 4 resists temperature up to 260° C. for short periods and up to 230° C. for long periods. Especially it is resistant to welding splashes. In addition it is resistant to a 5% salt fog according to a salt spray test and to ASTM B 117-64 216h.

Welding drops, which possibly deposit on such a coated surface, are easily removable from the surface without tools, the surface being not damaged.

As an alternative to the above described embodiment, according to a first coating variant the coating 4 is provided only at the upper side (I. e. the housing wall 3 of FIG. 2a) of the housing cover 1.

According to a second, particularly preferred coating variant, a complete coating of the surface is provided, but an only partial coating of the side walls with the second coating C is provided.

According to a third coating variant, the upper side 5 is provided with the complete coating 4, i.e. with both coatings B and C on the accordingly prepared base A, and all the other surfaces, i.e. also the inner surfaces, are provided exclusively with the second coating C, in which again all the surfaces are roughened and degreased. The application of the second coating C can occur in this case by means of dip varnishing.

Also in case of a partial coating with the first coating B and a complete coating with the second coating C it is possible to provide a complete degreasing, but it is possible to provide only a roughening of the area(s) provided with the first coating.

In this case a square housing is provided as first embodiment. Of course alternatively the housing can also have another useful shape according to the function, particularly it can be cylindrical, wherein in this case the upper side corresponds to a frontal surface, by means of which the measure is carried out, and the housing surfaces correspond to the peripheral surface.

Of course the coating 4 can be provided also in correspondence with the whole housing, i.e. especially also at the housing bottom.

The sensor itself instead of an inductive proximity switch 2 can be for example a capacitive sensor, an ultrasonic sensor or a magnetic sensor. In principle it can be also an optical sensor, wherein in this case the measuring side of the case is formed in a conventional way, i.e. not formed by means of the above described base and it is coated with said two coatings, or the measuring side is provided only with the second coating, which in this case has preferably a transparent form.

A corresponding coating, as described above on the basis of the embodiment and the various coating variants, is naturally possible also in case of RFID housing.

The following listing of table 1 comprises possible, preferred and particularly preferred areas of various abovementioned sizes in a base A made of steel, especially an austenitic steel, in which a first coating B of Aluminum-Titanium oxide is applied by means of thermal spraying and a second coating C consisting of a fluoropolymer varnish is applied.

TABLE 1
Possible, preferred and particularly preferred areas of single parameters

| | Possible without | | |
|---|---|---|---|
| | problems | Preferred | Particularly preferred |
| dA [mm] | 0.3-unlimited | 0.5-3.0 | 0.5-2.0 |
| dB [μm] | 20-200 | 30-100 | 30-70 |
| dC [μm] | 5.0-50.0 | 8.0-30.0 | 0.0-25.0 |
| Ra A [μm] | 1.9-5.0 | 2.1-4.6 | 2.36-4.19 |
| Rz A [μm] | 13.0-33.0 | 15.0-30.0 | 16.59-27.28 |
| Ra B [μm] | 3.5-6.5 | 3.9-5.9 | 4.37-5.40 |
| Rz B [μm] | 20.0-41.0 | 23.0-37.0 | 25.60-34.20 |
| Ra C [μm] | 2.4-4.9 | 2.7-4.5 | 3.03-4.11 |
| Rz C [μm] | 13.5-30.0 | 15.2-27.5 | 16.96-25.02 |
| dAB (penetration | 2.0-30.0 | 2.5-25.0 | 5.0-15.0 |
| depth B in A) [μm] | | | |
| dBC (penetration | 3.6-50.0 | 4.0-40.0 | 5.0-25.0 |
| depth C in B) [μm] | | | |
| Porosity B [Vol.-%] | 0.9-20 | 0.95-17 | 1.0-15 |

Although it has not been explicitly described above, a corresponding coating can obviously be provided also at the sensor mounting means, i.e. corresponding holders or other fastening means. While specific embodiments of the invention have been shown and described in detail to illustrate the application of the principles of the invention, it will be understood that the invention may be embodied otherwise without departing from such principles.

### APPENDIX

### Reference List

1 Housing cover
2 Proximity switch
3 Housing wall
4 Coating
5 Upper side
6 Side wall
A Base
AB Mixing layer
B first coating
BC Mixing layer
C second coating
dA Thickness of base A
dAB Thickness of mixing layer AB
dB Thickness of first coating
dBC Thickness of mixing layer BC
dC Thickness second coating C

What is claimed is:

1. A coated sensor or RFID housing comprising a housing cover comprising:
a base formed by a metal;
a double coating on at least one area of the base, the double coating comprising
a first coating of a porous ceramic on the base, the first coating being formed by an oxide ceramic with a lamellar structure;
a second coating provided on the first coating to provide the double coating, the second coating being formed by a fluoropolymer varnish, the second coating being at least partially incorporated into the first coating, wherein an outer surface structure of the double coating is an outer surface structure of the second coating over a major part of the outer surface structure of the double coating and the outer surface structure of the double coating is independent from a structure of the first coating.

2. A coated sensor or RFID housing according to claim 1, wherein the base is formed of austenitic steel.

3. A coated sensor or RFID housing according to claim 1, wherein the first coating is formed by Aluminum-Titanium oxide.

4. A coated sensor or RFID housing according to claim 1, wherein the second coating is formed by PTFE in connection with a thermosetting organic resin as a binding agent.

5. A coated sensor or RFID housing according to claim 1, wherein the first coating has a porosity from 0.9 to 20.0 Vol.-%.

6. A coated sensor or RFID housing according to claim 1, wherein a surface roughness depth Ra of the second coating is 2.4 to 4.9 μm.

7. A coated sensor or RFID housing according to claim 1, wherein the surface roughness depth Rz of the second coating is 13.5 to 30.0 μm.

8. A coated sensor or RFID housing according to claim 1, wherein the surface roughness depth Ra of the first coating is 3.5 to 6.5 μm.

9. A coated sensor or RFID-housing according to claim 1, wherein the surface roughness depth Rz of the first coating is 20.0 to 41.0 μm.

10. A coated sensor or RFID housing according to claim 1, wherein the surface roughness depths Ra and Rz of the base and the surface roughness depths Ra and Rz of the second coating are smaller than the surface roughness depths Ra and Rz of the first coating.

11. A coated sensor or RFID housing according to claim 1, wherein the surface roughness depths Ra and Rz of the base differ not more than about 10% with reference to the surface roughness depths Ra and Rz of the second coating.

12. A coated sensor or RFID housing according to claim 1, wherein a penetration depth of the first coating into the base is smaller than a penetration depth of the second coating into the first coating.

13. A coated sensor or RFID housing according to claim 1, wherein a penetration depth of the second coating into the first coating is at least equal to a surface roughness depth of the first coating.

14. A coated sensor or RFID housing according to claim 12, wherein a penetration depth of the second coating into the first coating is greater than a surface roughness depth of the first coating.

15. A coated sensor or RFID housing according to claim 1, wherein a thickness of the second coating is smaller than or equal to a penetration depth of the second coating into the first coating.

16. A coated sensor or RFID housing according to claim 1, wherein a penetration depth of the second coating into the first coating is 3.6 to 50.0 μm.

17. A coated sensor or RFID housing according to claim 15, wherein the penetration depth of the second coating into the first coating is 4.0 to 40.0 μm.

18. A coated sensor or RFID housing according to claim 16, wherein the penetration depth of the second coating into the first coating is 5.0 to 25.0 μm.

19. A coated sensor or RFID housing according to claim 1, wherein a penetration depth of the first coating into the base is 2.0 to 30.0 μm.

20. A coated sensor or RFID housing according to claim 1, wherein only a portion of the housing is provided with both coatings, and one or more other portions of the housing or another area of the housing is provided only with one of the two coatings.

21. A coated sensor or RFID housing according to claim 20, wherein the area of the housing provided with only one of the two coatings is provided only with the second coating.

22. An assembly comprising:
a coated sensor or RFID housing as well as sensor mounting means intended to fasten the sensor or RFID housing, wherein the sensor or RFID housing as well as the sensor mounting means are coated on at least one area of a base with a double coating comprising:
a first coating of a porous ceramic on the base, the first coating being formed by an oxide ceramic with a lamellar structure;
a second coating provided on the first coating to provide the double coating, the second coating being formed by a fluoropolymer varnish, the second coating being at least partially incorporated into the first coating, wherein an outer surface structure of the double coating is an outer surface structure of the second coating over a major part of the outer surface structure of the double coating and the outer surface structure of the double coating is independent from a structure of the first coating.

23. A process for forming coated sensor or RFID housing comprising:
providing a housing cover with a base formed by a metal;
forming a double coating on at least one area of the base, the double coating comprising
a first coating of a porous ceramic on the base, the first coating being formed by an oxide ceramic with a lamellar structure;
a second coating provided on the first coating to provide the double coating, the second coating being formed by a fluoropolymer varnish, the second coating being at least partially incorporated into the first coating, wherein an outer surface structure of the double coating is an outer surface structure of the second coating over a major part of the outer surface structure of the double coating and the outer surface structure of the double coating is independent from a structure of the first coating.
